(19) United States
(12) Patent Application Publication
(10) Pub. No.: US 2009/0109729 A1
(43) Pub. Date: Apr. 30, 2009

(54) RESISTANCE CHANGE MEMORY DEVICE AND METHOD FOR ERASING THE SAME

(75) Inventor: Haruki TODA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/257,029

(22) Filed: Oct. 23, 2008

(30) Foreign Application Priority Data
Oct. 24, 2007 (JP) 2007-275904

(51) Int. Cl. G11C 11/00; G11C 7/00

(52) U.S. Cl. 365/148; 365/218

(57) ABSTRACT

A resistance change memory device including a cell array with memory cells arranged therein to store a resistance value as data in a non-volatile manner, and an erase circuit configured to set the memory cells in the cell array in a reset state prior to data writing, wherein the erase circuit includes: an erase current generating circuit configured to output erase current of the cell array; multiple switch devices so disposed on current paths between the erase current generating circuit and the respective divided areas defined in the cell array as to supply the erase current to the divided areas; and a control circuit configured to sequentially turn on the switch devices.

### CROSS-REFERENCE TO RELATED APPLICATION

This application is based on and claims the benefit of priority from the prior Japanese Patent Application No. 2007-275904, filed on Oct. 24, 2007, the entire contents of which are incorporated herein by reference.

### BACKGROUND OF THE INVENTION

1. Field of the Invention

This invention relates to a resistance change memory device and a method for setting an initial state therein desirable for data writing.

2. Description of the Related Art

It has been proposed such a resistance change memory (ReRAM) that stores a resistance value as data, which is reversibly exchanged by applying voltage, current or heat, and it is noticed for succeeding to the conventional NAND-type flash memory. This resistance change memory is suitable for shrinking the cell size, and for constituting a cross-point cell array. In addition, it is easy to stack cell arrays.

Specifically, a unipolar type of ReRAM cell has such a feature that the high resistance state and low resistance state are reversibly settable by controlling the applied voltage and applying time thereof. For example, refer to Y. Hosoi et al, “High Speed Unipolar Switching Resistance RAM(RRAM) Technology” IEEE International Electron Devices Meeting 2006, Technical Digest, P. 793-796.

However, the resistance material of the memory cell shows such an asymmetric state change that a change from a high resistance state into a low resistance state and another change from a low resistance state into a high resistance state are different from each other in easiness and in the change time. Therefore, executing such an access that bidirectional changes are combined at random, the memory access cycle becomes irregular, and it is a fear that it becomes difficult to realize the memory.

### SUMMARY OF THE INVENTION

According to an aspect of the present invention, there is provided a resistance change memory device including a cell array with memory cells arranged therein to store a resistance value as data in a non-volatile manner, and an erase circuit configured to set the memory cells in the cell array in a reset state prior to data writing, wherein

the erase circuit includes:

an erase current generating circuit configured to output erase current of the cell array;

multiple switch devices so disposed on current paths between the erase current generating circuit and the respective divided areas defined in the cell array as to supply the erase current to the divided areas; and

a control circuit configured to sequentially turn on the switch devices.

According to another aspect of the present invention, there is provided a method of erasing a resistance change memory device including resetting the entire memory cells in a cell array area to be in a high resistance state prior to data writing therein, wherein the resetting procedure includes

sequentially supplying erase current to multiple divided areas of the cell array area.

### BRIEF DESCRIPTION OF THE DRAWINGS

FIG. 1 is a diagram for explaining the write cycle of a ReRAM.

FIG. 2 is a diagram for explaining the interface of the write data input portion of a ReRAM.

FIG. 3 is a diagram for explaining the erase progressing state in a case that a ReRAM is erased at once.

FIG. 4 shows a current change at the erase time of a ReRAM.

FIG. 5 shows an equivalent circuit for explaining the resistance dependency of the erase current, voltage and power of a ReRAM.

FIG. 6 shows the graph of the resistance dependency.

FIG. 7 shows an equivalent circuit of a cell array of a ReRAM in accordance with an embodiment.

FIG. 8 is a diagram for explaining the cell array erase in the embodiment.

FIG. 9 shows the relationship between the partial cell arrays PA and switch devices 21.

FIG. 10 shows an erase current change in this embodiment.

FIG. 11 shows a control scheme of the cell array erase in another embodiment.

FIG. 12 shows a flip-flop as a control circuit used in FIG. 11.

FIG. 13 shows the erase current change in this embodiment.

### DETAILED DESCRIPTION OF THE EMBODIMENTS

There is an erase scheme as one approach for making a ReRAM easily accessible, in which the whole cell array is made to be even in an initial state. However, to erase a large area of the cell array at once, it is in need of constituting an efficient erase system in consideration of the scale and ability of the circuit. For example, assuming that a cell's erase state is defined as a high resistance state, it is in need of supplying a large current at the beginning of an erase cycle for erasing a large cell array area at once.

In consideration of this situation, in the present invention, a cell array to be erased at once is divided into multiple divided areas, which are referred to as “partial cell arrays” hereinafter, and such an erase scheme is adapted that the partial cell arrays are sequentially erased. With this scheme, it becomes possible to make the erase power supply circuit system small in scale.

In detail, as the method of sequentially erasing the partial cell arrays, switch devices are disposed on the current paths between an erase power supply circuit and the partial cell arrays, and the number of on-state switches is increased in consideration of the respective erase times of the partial cell arrays. Even if an erased partial cell array is coupled to the erase power supply circuit as it is through an on-state switch device, it does not become a large load of the erase power supply circuit because cells in the erased partial cell array have been set in a high resistance state.

Technical elements in the embodiment described below will be summarized as follows:
In a resistance change memory device having memory cells, each resistance value of which is exchangeable as data with applied voltage, current or heat, a data state obtained through a long time state-transition is defined as an erase state, and there is provided an erase circuit, which is able to set an erase unit of a cell array to be in the erase state without a large current peak.
In a resistance change memory device having memory cells, each resistance value of which is exchangeable as data with applied voltage, current or heat, a data stream with an optional pattern of data “0” and “1” may be written in such a way that the data transition cycle time becomes constant without regard to data patterns.
In a resistance change memory device having memory cells, each resistance value of which is exchangeable as data with applied voltage, current or heat, a memory cell has a thermally stable high resistance state, which is defined as an erase state, and there is provided an erase circuit, which sequentially sets multiple partial cell arrays to be in the erase state, the partial cell arrays being defined in an erase unit of a cell array.
In a resistance change memory device having memory cells, each resistance value of which is exchangeable as data with applied voltage, current or heat, a memory cell has a thermally stable high resistance state, which is defined as an erase state, and there are disposed switch devices on the current paths between an erase current generating circuit and the respective partial cell arrays obtained by dividing a cell array. The switch devices are sequentially turned on, so that the partial cell arrays are sequentially changed into the erase state. As a control circuit for controlling on-timing of the switch devices, for example, CR delay circuits disposed between the respective switch devices are used. Alternatively, flip-flops are disposed at the respective switch devices, and sequentially set on receipt of that the preceding switch devices are turned on and the current supplied from an erase current generating circuit is reduced to a certain level or less, thereby turning on the corresponding switch device.

Prior to the detailed explanation of the embodiments, the background will be explained in detail.

A resistance change from a low resistance state into a high resistance state and another resistance change from the high resistance change into the low resistance state of a recording material of a ReRAM are based on different mechanisms from each other. That is, one state transition progresses at a greater rate than the other state transition, and the physical environment of the high-speed state transition is useful for constituting a circuit system.

For example, assume that a recoding layer of the variable resistance element is formed of a transition metal oxide layer, the resistance value of which is changed from a high resistance state into a low resistance state by applying voltage higher than a certain level, and from the low resistance state into the high resistance state by applying heat.

This recoding material, a high resistance state of which is a thermodynamically stable state, stores at least two levels of data in such a way that the high resistance state is defined as a reset state while a low resistance state is defined as a set state. Using three or more levels of resistance distributions, a multi-level data storage scheme will be achieved.

In case of the above-described memory cell, one data transition from the high resistance state to the low resistance state may be easily achieved by voltage generated from a simple circuit system, and memory cells are accessible at a high rate. Therefore, it becomes possible to perform a random writing access. However, it is necessary to take a long time for the other data transition from the high resistance state to the low resistance state because it is required of the cell to be applied with Joule's heat for a certain time. If bidirectional transitions are combined in a writing access, it is in need of changing the write cycle in accordance with the resistance state in the data writing destination and data to be written.

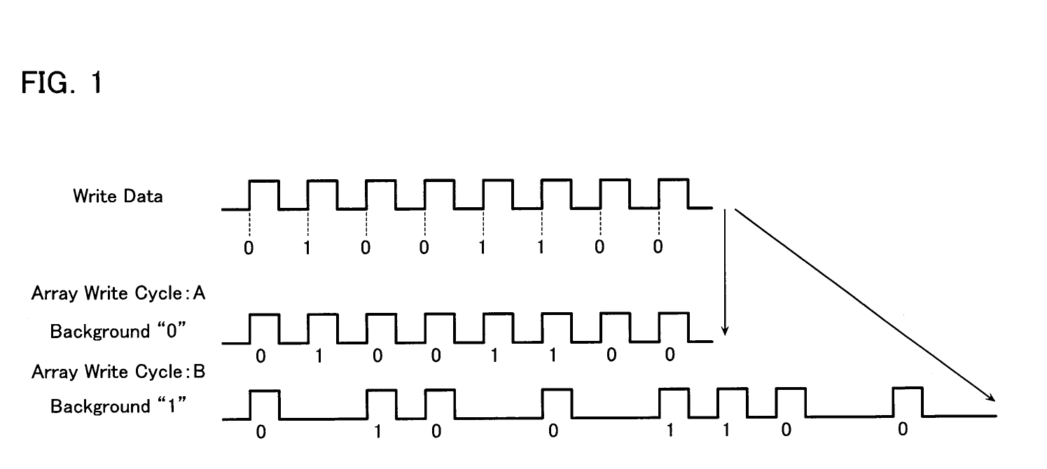

The details will be explained with reference to FIG. 1. To simplify the explanation, it is assumed that all cells in a cell array are set in a constant state, i.e., the background is in a constant resistance state. As write data, as shown in FIG. 1, a constant data stream is input to the interface portion.

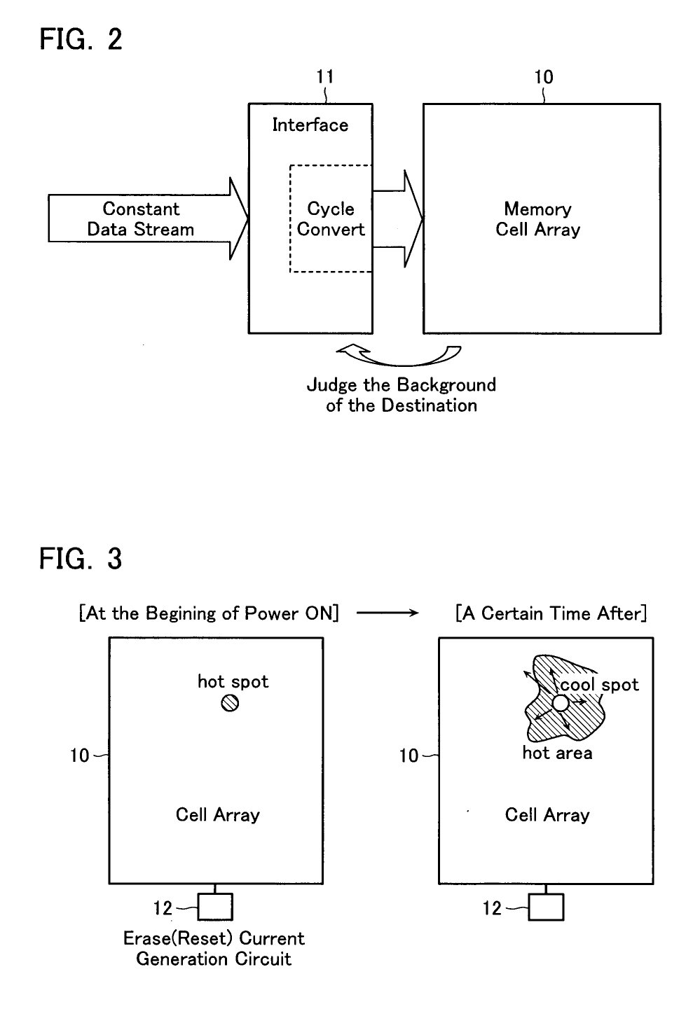

As shown in FIG. 2, the interface portion 11 judges the background of the destination in the memory cell array 10, and changes the write cycle in accordance with data of the data stream. In FIG. 1, there are shown write cycle “A” in case of the background is “0” and write cycle “B” in case the background is “1”.

Here, “0” is a high resistance state of a cell while “1” is a low resistance state. In case the background is “0”, the state transition time of “1” write is short, so that there is not so difference between write data cycle and array write cycle “A” as shown in FIG. 1. By contrast, in case the background is “1”, “0” write corresponds to such a data transition that it takes a long time. If “0” write is necessary to take a time twice as long as “1” write, array write cycle “B” becomes irregular as shown in FIG. 1.

This situation is not desirable for a memory system, which is required to transfer data at a constant rate and write them into the cell array. In this situation, it is effective to perform an erase operation for previously making the background of the memory cell array even in a “0” data state during an idle period of the memory cycle. In this case, however, to erase a large memory cell array area, it is in need of generating a great heat.

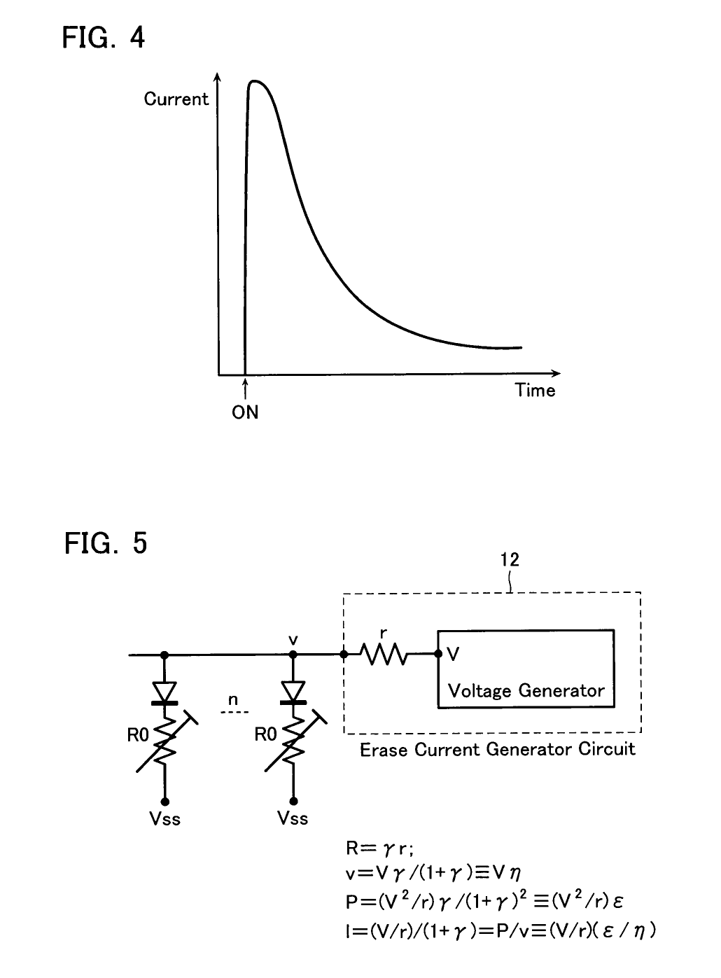

This situation will be explained in detail with reference to FIGS. 3 and 4.

Cell array 10 to be erased is usually written in such a state that “0”-cells and “1”-cells are mixed. When referring to as a resistance array, it is referred to as such a low resistance “cluster” that resistance distribution thereof is irregular.

To apply voltage to the cluster for subjecting it to Joule's heat, it is required of erase current generating circuit (erase power supply circuit) 12 to be in a low output impedance state and a highly drivable state.

In such a situation that state transition to the reset state (high resistance state) starts in the cell array 10, current flows in the whole cell array at the beginning of power supplying, and it will be generated a hot spot, i.e., an area with hot temperature. This hot spot area is made to be highly resistive, and resulting in that the Joule's heat generation is suppressed, and the hot spot is changed to a cool spot with a low temperature. As a result, the hot area is diffused to the periphery, and then the whole high resistance state will be obtained.

Noticing the power supply circuit in the above-described situation, the current will be changed as shown in FIG. 4. That is, a great current flows in the instant of turning on the power supply circuit, and the current value is gradually reduced as the hot area is increased. The initially supplied current, which flows until when the hot spot is generated, is very great, and this becomes a material element, with which the property of the power supply circuit is decided. That is, if the power supply circuit is designed without a large dynamic range, a sufficient hot spot is not generated by the initially supplied current, so that it takes a long time for erasing the cell array. Therefore, it is in need of improving the power supply circuit such that a hot spot is easily generated, and the load is reduced effectively.

Prior to the explanation of the method of improving the power supply circuit, it will be explained the relationship between the cell array resistance and cell array's current and voltage.

As shown in FIG. 5, erase current generating circuit 12 is expressed by a voltage generating circuit for generating voltage “V” and serial resistance “r” disposed between the voltage output node and the cell array. Assuming that the resistance of the cell array to be erased simultaneously is “R”, voltage “v” applied to the cell array and current “I” flowing in the cell array are expressed as follows: v=RV/(R+r); and I=V/(R+r). Note here that in case a memory cell is formed of a variable resistance element and a diode connected in series, the forward-directional voltage drop of the diode is neglected.

Assuming that the cell resistance in a set state (low resistance state) is “R0”; the number of cells stayed in the low resistance state in the cell array is “n”; and a parameter, which is introduced to show how many times as large as the resistance “r” is the cell array resistance “R”, is “γ”, the cell array resistance “R” will be expressed as follows:

R=R0/n=γr

Here is supposed that R0<r, and “γ” is smaller than 1 and inversely proportional to “n”. Further, introducing other parameters “ε” and “η”, cell array voltage “v”, cell array current “I” and cell array power “P” will be expressed as follows:

v=Vγ/(1+γ)≡Vη

P=(V²/r)γ/(1+γ)²≡(V²/r)ε

I=(V/r)/(1+γ)=P/v≡(V/r)(ε/η)

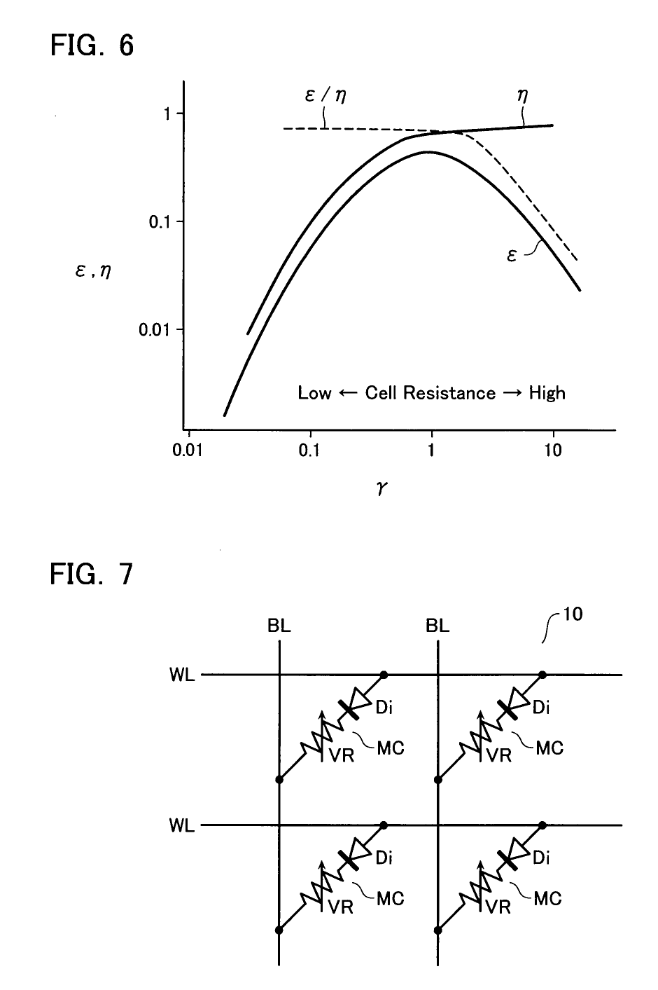

FIG. 6 shows the relationships between “γ” and “ε”, “η”. As described above, in case “γ” is inversely proportional to the set cell number “n”, and “R0” is smaller than “r”, “γ” is a parameter smaller than 1. As erase progresses and the number of high resistance cells is increased, the number of low resistance cells, “n”, is decreased, and “γ” is rapidly increased over 1.

“η” is a function of designating a γ-dependency of cell array voltage “v”. This is increased substantially in proportion to “γ” until about γ=1, and saturated at about 1 when “γ” is over 1. “ε” is a function of designating a γ-dependency of cell array power “P”. This is increased substantially in proportion to “γ” until about γ=1 as similar to “η” to have a peak at γ=1, and becomes substantially inversely proportional to “γ” while it is over 1. “ε/η” is a function of designating a γ-dependency of cell array current “I”. This is not dependent on “γ” and kept at about 1 until when γ=1, and becomes substantially inversely proportional to “γ” while it is over 1.

Therefore, large current flows at the beginning of the erase cycle when voltage is applied from the erase current generating circuit, and this state will be kept for some time (ε/η). During this time, the cell array temperature rises gradually by Joule's heat. After a while, there is generated a hot spot in the cell array, which is necessary for the state transition of the cell array, and cell's erase progresses in accordance with the diffusion of Joule's heat. When the cell array erase is completed, n=0 is obtained, and “γ” becomes great rapidly, whereby the generation of Joule's heat stops (ε); the cell array voltage becomes the output of the voltage generating circuit (η); and the cell array current decreases rapidly (ε/η).

In consideration of the above-described situation, it will be explained below a method of easily making a hot spot and reducing the load of the erase power supply circuit.

Cell array 10 is, as shown in FIG. 7, formed of multiple word lines WL; multiple bit lines BL crossing the word lines WL; and memory cells MC disposed at the respective cross-points of the word lines and bit lines. Memory cell MC is formed of variable resistance element VR and diode Di connected in series. To constitute a ReRAM with a large capacity, the cell arrays are stacked three-dimensionally.

Data write, read and erase are performed with such voltage application as to forward-bias the cell diode Di in a memory cell selected by a selected word line and a selected bit line. In this case, set, i.e., write operation (transition from a high resistance state to a low resistance state), read operation (cell current detection) and reset, i.e., erase operation (transition from a low resistance state to a high resistance state) are distinguishably executed by controlling the applied voltage level and voltage applying time.

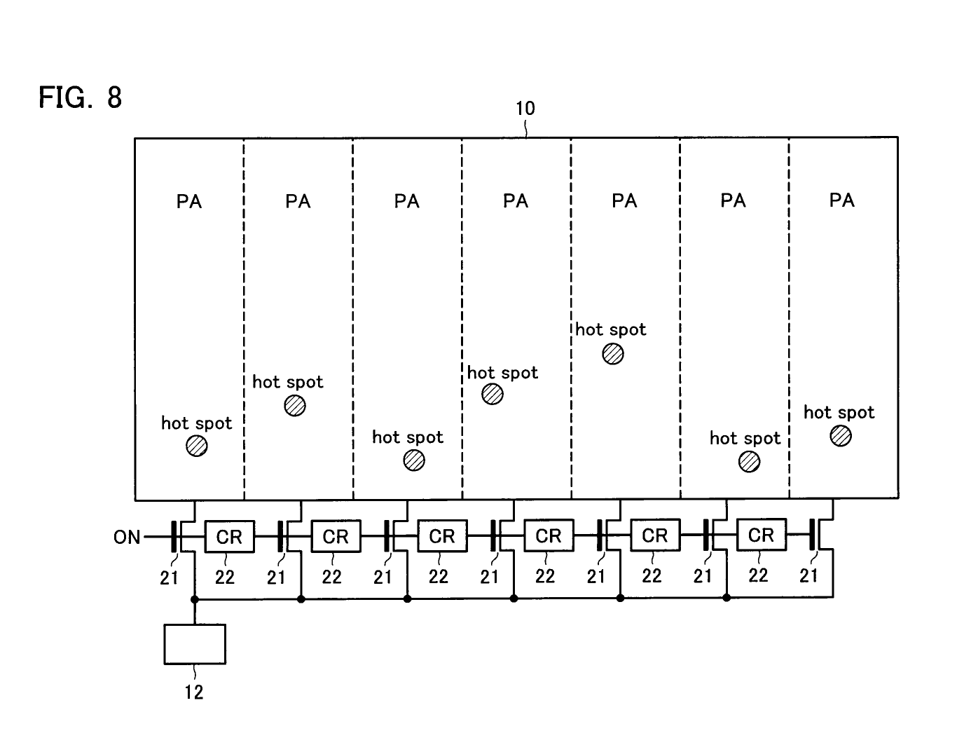

As shown in FIG. 8, according to this embodiment, to erase the cell array at a high rate while generating hot spots therein, cell array 10 is divided into some divided areas, i.e., partial cell arrays PA. Disposed on the current paths between erase current source circuit 12 and the respective partial cell arrays PA are switching devices 21 such as transistors. To sequentially turn on the switching devices 21, CR delay circuits 22 are disposed between the respective control nodes (gate nodes) of the switching devices and the preceding control nodes. Input to the control node of the first stage switching device 21 is an external driving signal ON.

With this erase circuit, when the switching device driving signal ON is input, switching devices 21 disposed on the current paths are sequentially turned on with delay times determined by the delay circuits 22, whereby erase currents may be sequentially supplied to the partial cell arrays PA in the cell array 10.

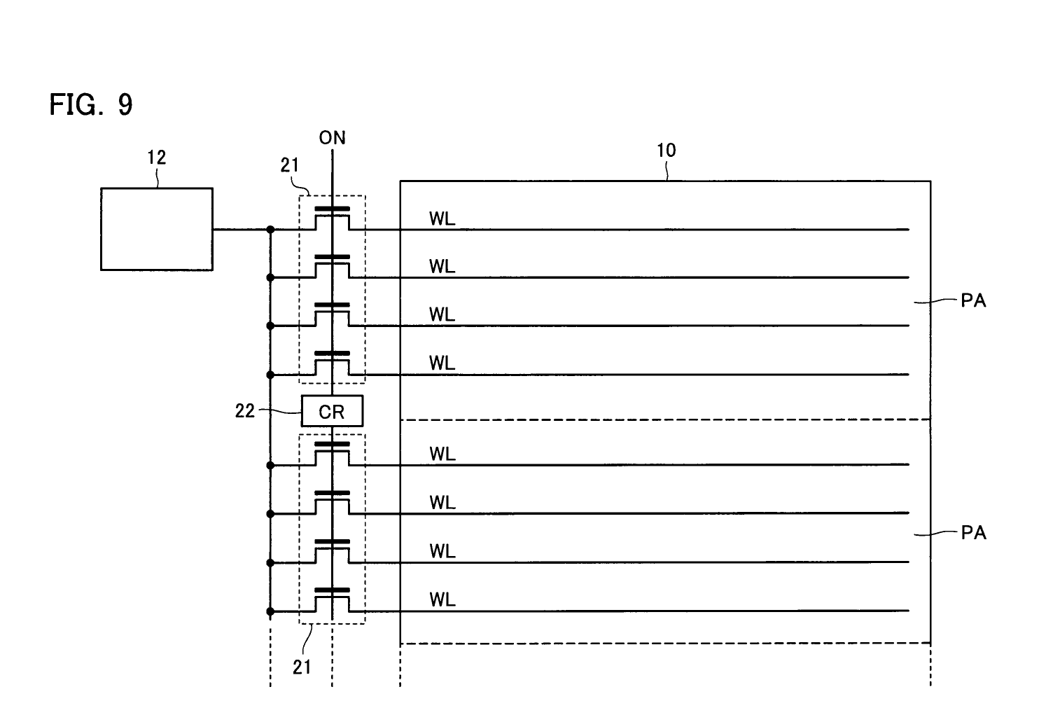

In detail, it is assumed that the partial cell array PA is, for example as shown in FIG. 9, defined as a cell area including multiple word lines. In this case, as shown in FIG. 9, each switching device 21 is formed of a transistor array, in which multiple transistors are arranged with a common gate to be coupled to the respective word lines, and the common gate is coupled to the following common gate via delay circuit 22. With this configuration, the partial cell arrays PA are sequentially subjected to erase in such a way that the multiple word lines in each partial cell array PA may be supplied with erase current simultaneously.

Note here that cell array 10 shown in FIG. 8 is in detail a unit area to be erased at once, i.e., erase unit. That is, cell array 10 shown in FIG. 8 is defined as not only a cell array but also an erase unit in a large cell array including multiple erase units.

The erase method by use of the above-described current supplying scheme will be referred to as a “stagger erase” scheme hereinafter. In the stagger erase scheme, to generate certainly a hot spot in the partial cell array PA, it is material to select a time interval of sequentially turning on the switch devices 21 and a size of the exclusive partial cell array PA adapted to the drivability of the erase current generating circuit 12.

The drivability of the erase current generating circuit 12 and the size of the partial cell array PA are set to have such a relationship that is able to supply a current to the partial cell array PA necessary for certainly generating a hot spot even if all cells in the partial cell array PA are in the low resistance state. If only the partial cell array PA is continuously supplied with current, a hot spot will be generated at the peak of the initial supplying current. As the cell's state transition to the high resistance state progresses with a seed defined by the hot spot, and the whole of the partial cell array PA becomes in the high resistance state, the current supplied from the erase current generating circuit 21 is reduced.

At a suitable timing when the above-described erase current is reduced, switch device 21 on the current path of the following partial cell array PA is tuned on, so that power supply circuit 21 with a sufficient drivability restored starts to supply current to this partial cell array PA. The CR time constant of delay circuit 22 is set as to make the above-described current supplying possible. All partial cell arrays are sequentially supplied with current as explained above, and the erase sequence ends in such a state that the whole of the cell arrays 10 is set in the high resistance state.

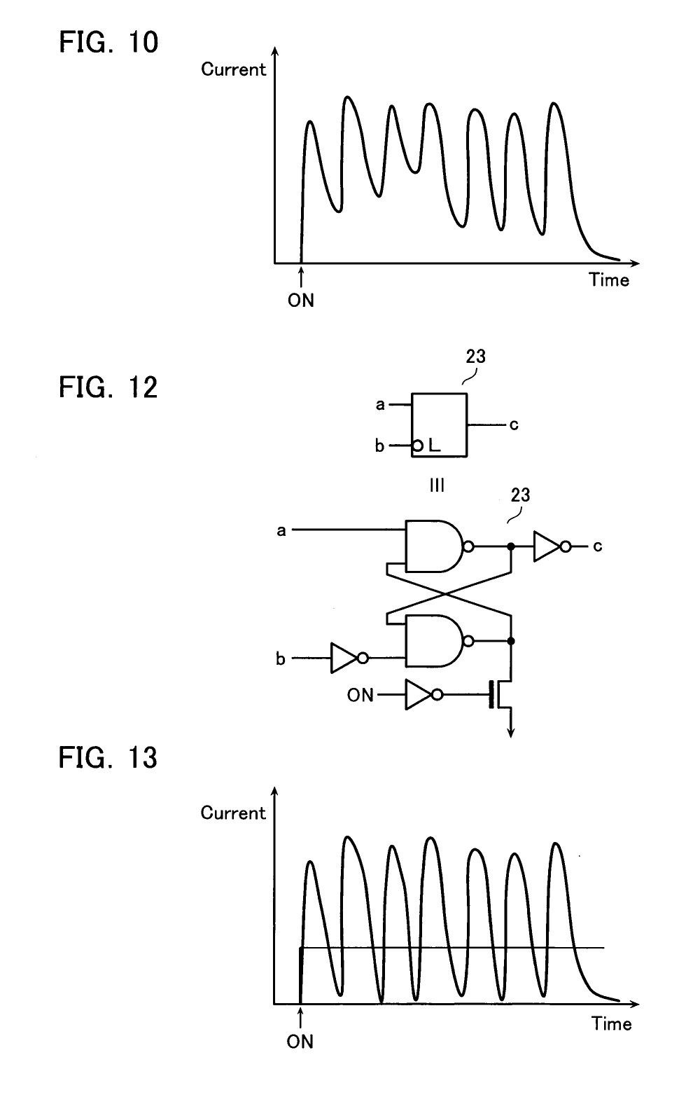

FIG. 10 shows the output current change of the current generating circuit 12 during the above-described erase operation with the lateral axis designating time after inputting the drive signal ON. The partial cell arrays PA are sequentially driven, and current peaks appear at the respective drive-starting timings. Assuming that the division number of the partial cell arrays is N, the current peak becomes 1/N in comparison with that in case the whole cell array 10 is erased at once. That is, it becomes possible to erase the cell array with an erase circuit with a relatively low drivability.

The erase unit of the cell array being subjected to erase prior to data writing as described above, the cycle time of data transferring becomes constant without regard to the write data pattern input at the write time.

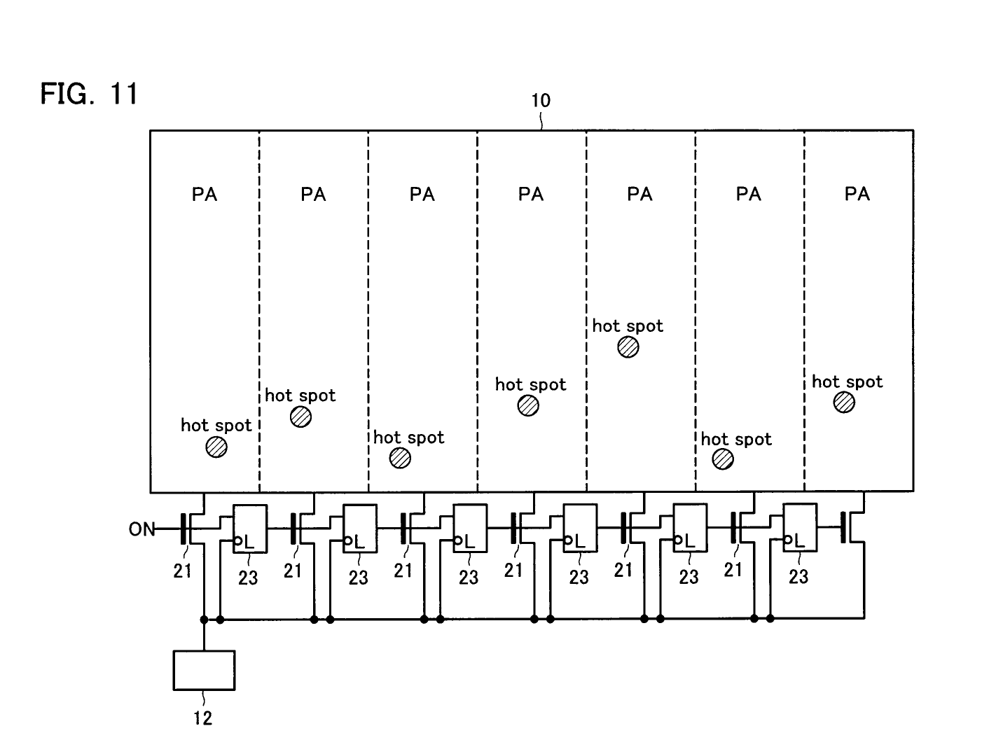

FIG. 11 is a diagram corresponding to FIG. 8 in accordance with another embodiment. In this embodiment, a state transition circuit, for example flip-flop 23 as shown in FIG. 12, is used in place of the CR delay circuit 22 for controlling the current path switching devices 21 for the partial cell arrays PA. With this flip-flop 23, it becomes possible to turn on the following switch device after when the erase operation for a partial cell array PA has been completed substantially.

When the erase of a partial cell array PA ends, the erase current generating circuit 12 stops outputting current, and starts in boosting the output voltage. Regarding this output voltage boosting as an erase end signal of a partial cell array PA, it is possible to turn on the switch device 21 of the following partial cell array PA. That is, the initial stage device 21 is turned on by the external drive signal ON while the successive switch devices of other partial cell arrays are driven by the flip-flops 23.

Flip-flops 23 are reset when the drive signal ON becomes inactive. Flip-flops 23 have two inputs “a” and “b”, which receive that the preceding switch device 21 becomes on and that the output voltage of the erase current generating circuit 12 is boosted, respectively. Therefore, inputs “a” and “b” becoming “H”, flip-flop 23 is set, so that output “c” becomes “H”. This output signal “c” is used as a control signal (gate input signal) of the switch device 21.

FIG. 13 shows an erase current change together with drive signal ON in this embodiment. When an erase operation of a partial cell array PA ends, and current thereof becomes less, the output voltage of the erase current generating circuit 12 becomes high. In receipt of it, flip-flop 23 outputs “H” to turn on the switch device 21 corresponding to the following partial cell array PA.

According to the above-described switching control, it becomes possible to certainly erase the partial cell arrays.

This invention is not limited to the above-described embodiment. It will be understood by those skilled in the art that various changes in form and detail may be made without departing from the spirit, scope, and teaching of the invention.

What is claimed is:

1. A resistance change memory device comprising a cell array with memory cells arranged therein to store a resistance value as data in a non-volatile manner, and an erase circuit configured to set the memory cells in the cell array in a reset state prior to data writing, wherein
the erase circuit comprises:
an erase current generating circuit configured to output erase current of the cell array;
multiple switch devices so disposed on current paths between the erase current generating circuit and the respective divided areas defined in the cell array as to supply the erase current to the divided areas; and
a control circuit configured to sequentially turn on the switch devices.

2. The resistance change memory device according to claim 1, wherein
the reset state of the memory cell is a high resistance state.

3. The resistance change memory device according to claim 1, wherein
the memory cell has a variable resistance element for storing a resistance value and a diode connected in series, the variable resistance element storing data with at least two levels of a set state and the reset state defined by a first resistance value and a second resistance value higher than the first resistance value, respectively, the reset state being obtained through a thermal process with current applied to the memory cell while the set state is obtained by applying voltage to the memory cell.

4. The resistance change memory device according to claim 1, wherein
the control circuit comprises delay circuits disposed between the control nodes of the respective switch devices and the preceding control nodes.

5. The resistance change memory device according to claim 4, wherein
the delay circuits sequentially drive the respective switch devices at intervals defined by CR time constants of the delay circuits.

6. The resistance change memory device according to claim 1, wherein
the control circuit comprises state transition circuits disposed between the control nodes of the respective switch devices and the preceding control nodes, the state transition circuits being set with the driving signals at the preceding control nodes and the output voltage of the erase current generating circuit to sequentially drive the respective switch devices.

7. The resistance change memory device according to claim 1, wherein
The initial stage of the multiple switch devices is driven by an external drive signal.

8. The resistance change memory device according to claim 1, wherein
the divided area includes multiple word lines, and the switch device is formed of multiple transistors coupled to the respective word lines with a common gate.

9. The resistance change memory device according to claim 1, wherein
the divided areas are defined by dividing an erase unit to be erased at once in the cell array.

10. A method of erasing a resistance change memory device comprising resetting the entire memory cells in a cell array area to be in a high resistance state prior to data writing therein, wherein the resetting procedure comprises
sequentially supplying erase current to multiple divided areas of the cell array area.

11. The method according to claim 10, wherein
the resetting procedure further comprises switching the erase current supplying to the divided areas at intervals defined by CR time constant circuits.

12. The method according to claim 10, wherein
the resetting procedure further comprises switching the erase current supplying to the divided areas in accordance with a detection signal of the erase current decreasing.

13. The method according to claim 10, wherein
the resistance change memory device having memory cells each formed of a variable resistance element for storing a resistance value and a diode connected in series, the variable resistance element storing data with at least two levels of a set state and the reset state defined by a first resistance value and a second resistance value higher than the first resistance value, respectively, the reset state being obtained through a thermal process with current applied to the memory cell.
